(19) United States
(12) Patent Application Publication
(10) Pub. No.: US 2009/0114998 A1
(43) Pub. Date: May 7, 2009

(54) SEMICONDUCTOR DEVICE AND METHOD FOR FABRICATING SAME

(76) Inventor: Yoshiya MORIYAMA, Osaka (JP)

Correspondence Address: MCDERMOTT WILL & EMERY LLP, 600 13TH STREET, NW, WASHINGTON, DC, 20005-3096, US

(21) Appl. No.: 12/261,431

(22) Filed: Oct. 30, 2008

(30) Foreign Application Priority Data
Nov. 2, 2007 (JP) 2007-286228

(51) Int. Cl. H01L 27/088; H01L 21/28

(52) U.S. Cl. 257/392; 438/591; 257/E27.06; 257/E21.177

(57) ABSTRACT

A first MIS transistor is formed in a low voltage transistor formation region and includes a gate insulating film and a first gate electrode composed of a metal film and a polycrystalline silicon film. A second MIS transistor is formed in a high voltage transistor formation region and includes a gate insulating film and a second gate electrode composed of a polycrystalline silicon film. An equivalent oxide thickness of the gate insulating film formed in the low voltage transistor formation region is thinner than an equivalent oxide thickness of the gate insulating film formed in the high voltage transistor formation region. A level of the surface of a semiconductor substrate in the low voltage transistor formation region is higher than a level of the surface of a semiconductor substrate in the high voltage transistor formation region.

### BACKGROUND OF THE INVENTION

The present invention relates to a semiconductor device which has an MIS type transistor structure having a metal gate electrode and to a fabrication method of the same.

In recent years, there has been an increasing demand for the lower power consumption and higher speed of the operation of semiconductor integrated circuits. For example, drive current of semiconductor integrated circuits has been improved, in other words, speed of operation of semiconductor integrated circuits has been enhanced by reducing the thickness of a gate insulating film while lowering a supply voltage to reduce power consumption. However, many of the semiconductor integrated circuits use a plurality of supply voltages. For example, there is a case where a logic circuit or SRAM (Static Random Access Memory) is driven by 1.2 V or 1.5 V, while an I/O circuit is driven by 3.3 V or 5 V. If a plurality of supply voltages are used, an MIS transistor including a gate insulating film having a thickness corresponding to each supply voltage is necessary. For example, the MIS transistor driven by 1.2 V has a gate insulating film whose equivalent oxide thickness is about 2 nm, while the MIS transistor driven by 3.3 V has a gate insulating film whose equivalent oxide thickness is about 7 nm.

In general, when forming two or more gate insulating films each having a different thickness, the thickest gate insulating film is formed first by the combination of thermal oxidation, photolithography, and wet etching using HF or BHF, and these processes are sequentially repeated to obtain a gate insulating film having a different thickness before the thinnest gate insulating film is lastly formed (see, for example, Japanese Laid-Open Patent Publication No. 2001-284469).

A fabrication method of a conventional semiconductor device of this type is hereinafter described with reference to the drawings.

FIG. 8A through FIG. 8D and FIG. 9A through FIG. 9D are cross sections of a conventional semiconductor device which are arranged in the order of steps of the fabrication method. Described below is an example in which an MIS transistor having a thin gate insulating film is formed in a semiconductor substrate 101a and an MIS transistor having a thick gate insulating film is formed in a semiconductor substrate 101b. The low voltage transistor formation region A is a region where an MIS transistor driven by the supply voltage of 1.2 V (hereinafter, referred to as 1.2-volt transistor) is formed as an MIS transistor having a thin gate insulating film, and the high voltage transistor formation region B is a region where an MIS transistor driven by the supply voltage of 3.3 V (hereinafter, referred to as 3.3-volt transistor) is formed as an MIS transistor having a thick gate insulating film.

First, a sacrificial oxide film 102 is formed on the semiconductor substrates 101a and 102b as shown in FIG. 8A.

Next, as shown in FIG. 8B, isolation regions 103 are selectively formed in the upper portions of the semiconductor substrates 101a and 102b using, for example, an STI (shallow trench isolation) method, such that the isolation regions 103 define the low voltage transistor formation region A and the high voltage transistor formation region B.

Next, as shown in FIG. 8C, impurity layers 104a and 104b for controlling threshold voltage are formed in the upper portions of the semiconductor substrates 101a and 102b, respectively, by ion implantation. Herein, the sacrificial oxide film 102 has the function of preventing channeling during the ion implantation.

Next, as shown in FIG. 8D, the sacrificial oxide film 102 is removed by wet etching using HF, BHF or the like, to expose the surfaces of the semiconductor substrates 101a and 102b.

Next, as shown in FIG. 9A, a thick gate insulating film 105 having a thickness of about 7 nm is formed on the semiconductor substrates 101a and 102b by thermal oxidation. Since the gate insulating film 105 is formed by thermal oxidation, the surfaces of the semiconductor substrates 101a and 102b recede during the thermal oxidation. The reduced thickness d101 is about half the thickness of the formed thick gate insulating film 105, that is, about 3.5 nm.

Next, as shown in FIG. 9B, a resist pattern 106 having an opening in a region corresponding to the low voltage transistor formation region A is formed by lithography or an etching, and using this resist pattern 106 as a mask, the thick gate insulating film 105 is removed from the surface of the semiconductor substrate 101a by wet etching using HF, BHF or the like, to expose the surface of the semiconductor substrate 101a.

Next, as shown in FIG. 9C, a thin gate insulating film 107 having a thickness of about 2 nm is formed on the surface of the semiconductor substrate 101a by thermal oxidation. Similar to the step of FIG. 9A, since the thin gate insulating film 107 is formed by thermal oxidation, the surface of the semiconductor substrate 101a recedes during the thermal oxidation. The reduced thickness d102 is about half the thickness of the formed thin gate insulating film 107, that is, about 1.0 nm.

Next, as shown in FIG. 9D, a polycrystalline silicon film 108 to serve as a gate electrode is formed by CVD on the thick gate insulating film 105, the thin gate insulating film 107, and the isolation regions 103.

### SUMMARY OF THE INVENTION

According to the above method for forming a conventional semiconductor device, the thickness of the semiconductor substrate 101a in the low voltage transistor formation region A is reduced by the depth that is equal to the sum of the reduced thicknesses d101 and d102 during a period of time from when the impurity layers 104a and 104b are formed in the step of FIG. 8C until when the thin gate insulating film 107 is formed in the step of FIG. 9C. In other words, the thickness of the impurity layer 104a, which is provided for controlling threshold voltage, is reduced by the depth that is equal to the above sum. This reduction in thickness influences change in threshold voltage. In addition, the reduced thicknesses d101 and d102 vary among devices or within a wafer plane; therefore, the threshold voltage also varies accordingly. In particular, since the gate insulating film 105 shown in FIG. 9A is greater in thickness than the gate insulating film 107 shown in FIG. 9C, the reduced thickness d101 is greater than the reduced thickness d102 at the surface of the semiconductor substrate 101a. The reduced thickness d101 at the surface of the semiconductor substrate 101a accordingly has greater variations.

Change in threshold voltage because of change in impurity concentration near the surface of the semiconductor substrate 101a becomes more significant as the thickness of the gate insulating film is reduced. Thus, if more progress is made in reducing the thickness of gate insulating films with the enhancement of speed of semiconductor integrated circuits, such variations in threshold voltage as mentioned in the above may become more noticeable.

On the other hand, the reduction in thickness of the gate insulating film is necessary in order to reduce power consumption and increase speed of semiconductor integrated circuits. However, if the gate insulating film is a silicon oxide film with a thickness of about 2 nm or less, leakage becomes significant between a semiconductor substrate and a gate electrode. In addition, gate depletion is caused if the material of the gate electrode formed on the gate insulating film is polycrystalline silicon as used in the step of FIG. 9D. The effective thickness of the gate insulating film therefore becomes greater than the physical thickness of the gate insulating film. Effects of the gate depletion cannot be easily reduced until voltage applied to the gate is lowered. Therefore the thinner the physical thickness of the gate insulating film is, the greater the effects of the gate depletion are. In other words, if the thickness of the gate insulating film is in a range of several nanometers, gate drivability is not much improved by just reducing the physical thickness of the gate insulating film.

In connection with this, the structure has been developed in which a high dielectric constant insulating film is used as a gate insulating film and a metal film is used as a gate formed on the gate insulating film. The use of a high dielectric constant insulating film as a gate insulating film increases the physical thickness of the gate insulating film, thereby suppressing gate leakage, and reduces the equivalent oxide thickness of the gate insulating film, thereby improving gate drivability. Further, the use of a metal film as a gate prevents gate depletion. It is therefore possible to improve the gate drivability without the effect of gate depletion, even if the equivalent oxide thickness of the gate insulating film is reduced.

In view of the above, an object of the present invention is to provide a semiconductor device including an MIS transistor in which a high dielectric constant gate insulating film and a metal gate are used and which has a plurality of gate insulating films each having a different thickness, wherein surface reduction of a semiconductor substrate is reduced and variations in the reduced thickness of the semiconductor substrate are diminished, and to provide a fabrication method of the same.

To achieve the above object, a semiconductor device according to an embodiment of the present invention includes a first MIS transistor in a first region of a semiconductor substrate and a second MIS transistor formed in a second region of the semiconductor substrate that is different from the first region, wherein the first MIS transistor includes: a first gate insulating film formed in the first region; and a first gate electrode formed of a metal film and a polycrystalline silicon film, which are stacked in this order on the first gate insulating film, the second MIS transistor includes: a second gate insulating film formed in the second region; and a second gate electrode formed of a polycrystalline silicon film on the second gate insulating film, an equivalent oxide thickness of the first gate insulating film is thinner than an equivalent oxide thickness of the second insulating film, and a level of a surface of the semiconductor substrate in the first region is higher than a level of a surface of the semiconductor substrate in the second region.

In the semiconductor device according to an embodiment of the present invention, the first gate insulating film includes an insulating film whose dielectric constant is higher than that of a silicon oxide film.

In the semiconductor device according to an embodiment of the present invention, the second gate insulating film is a silicon oxide film.

The semiconductor device according to an embodiment of the present invention further includes an isolation region which defines each of the first region and the second region and electrically separates the first region and the second region from one another, wherein at a boundary between the first and second regions a level of the isolation region on the first region side is higher than a level of the isolation region on the second region side.

The semiconductor device according to an embodiment of the present invention further includes an isolation region which defines each of the first region and the second region and electrically separates the first region and the second region from one another, wherein a depth of a recess of the isolation region in the first region is shallower than a depth of a recess of the isolation region in the second region.

In the semiconductor device according to an embodiment of the present invention, the first MIS transistor is a low voltage transistor, and the second MIS transistor is a high voltage transistor.

In the semiconductor device according to an embodiment of the present invention, the first MIS transistor and the second MIS transistor have the same conductivity type.

A method for fabricating a semiconductor device according to an embodiment of the present invention includes the steps of: (a) forming a first gate insulating film and a metal film in this order in a first region and a second region of the semiconductor substrate; (b) removing the metal film in the second region; (c) after step (b) removing the first gate insulating film in the second region; (d) after step (c) forming in the second region a second gate insulating film having an equivalent oxide thickness greater than an equivalent oxide thickness of the first gate insulating film, with the first gate insulating film and the metal film remaining in the first region; (e) after step (d) forming a polycrystalline silicon film on the metal film exposed in the fist region and on the second gate insulating film exposed in the second region; and (f) patterning the polycrystalline silicon film and the metal film to form a first gate electrode composed of the metal film and the polycrystalline silicon film on the first gate insulating film in the first region and form a second gate electrode composed of the polycrystalline silicon film on the second gate insulating film in the second region.

The method of the semiconductor device according to an embodiment of the present invention further includes the step (g) of forming a mask film for covering the metal film in the first region after step (b) and before step (c), wherein step (c) includes removing the first gate insulating film in the second region by etching using the mask film as a mask.

In the method of the semiconductor device according to an embodiment of the present invention, step (g) includes the steps of: (g1) forming a silicon nitride film in the first region and the second region; and (g2) removing the silicon nitride film in the second region by dry etching using a resist pattern covering the silicon nitride film in the first region as a mask, thereby obtaining the mask film composed of the silicon nitride film.

In the method of the semiconductor device according to an embodiment of the present invention, step (g) includes the steps of: (g1) forming a silicon nitride film in the first region and the second region; and (g2) removing the silicon nitride film in the second region by wet etching using a silicon oxide film covering the silicon nitride film in the first region as a mask, thereby obtaining the mask film composed of the silicon nitride film.

In the method of the semiconductor device according to an embodiment of the present invention, step (b) includes the steps of: (b1) forming a silicon nitride film on the metal film in the first and second regions; (b2) removing the silicon nitride film in the second region, thereby obtaining a mask film composed of the silicon nitride film covering the metal film in the first region; and (b3) removing the metal film in the second region by etching using the mask film as a mask, and step (c) includes removing the first gate insulating film in the second region by etching using the mask film as a mask.

In the method of the semiconductor device according to an embodiment of the present invention, step (d) includes the step of forming the second gate insulating film by thermal oxidation using the mask film as a mask for preventing oxidation.

In the method of the semiconductor device according to an embodiment of the present invention, step (d) includes the step of forming a first silicon oxide film by thermal oxidation and then forming a second silicon oxide film on the first silicon oxide film by CVD, thereby obtaining the second gate insulating film composed of the first silicon oxide film and the second silicon oxide film.

In the method of the semiconductor device according to an embodiment of the present invention, step (a) includes the step of forming in the first and second regions a silicon oxide film and an insulating film having a dielectric constant higher than a dielectric constant of the silicon oxide film in this order, thereby obtaining the first gate insulating film.

In the method of the semiconductor device according to an embodiment of the present invention, step (c) includes the step of removing the first gate insulating film by wet etching using hydrofluoric acid.

According to the semiconductor device of the present invention and the fabrication method thereof, surface reduction of a semiconductor substrate of an MIS transistor having a thin gate insulating film is reduced, whereby it is possible to diminish variations in thickness reduction of the semiconductor substrate, in a semiconductor integrated circuit including a gate insulating film having two or more different thicknesses and including a high dielectric constant gate insulating film and a metal gate. As a result, variations in threshold voltage of the MIS transistor are reduced.

### BRIEF DESCRIPTION OF THE DRAWINGS

FIG. 1A through FIG. 1D are cross sections of main structures of a semiconductor device according to an embodiment of the present invention which are arranged in the order of steps of the fabrication method.

FIG. 2A through FIG. 2D are cross sections of main structures of a semiconductor device according to an embodiment of the present invention which are arranged in the order of steps of the fabrication method.

FIG. 3A through FIG. 3D are cross sections of main structures of a semiconductor device according to an embodiment of the present invention which are arranged in the order of steps of the fabrication method.

FIG. 4 is a profile of impurity near the semiconductor substrate surface according to an embodiment of the present invention, showing the relationship between the impurity concentration and the depth.

FIG. 5 is a cross section taken along a gate width according to an embodiment of the present invention.

FIG. 6A through FIG. 6D are cross sections of main structures of a semiconductor device according to Variation 1 of an embodiment of the present invention which are arranged in the order of steps of the fabrication method.

FIG. 7A through FIG. 7C are cross sections of main structures of a semiconductor device according to Variation 2 of an embodiment of the present invention which are arranged in the order of steps of the fabrication method.

FIG. 8A through FIG. 8D are cross sections of main structures of a conventional semiconductor device which are arranged in the order of steps of the fabrication method.

FIG. 9A through FIG. 9D are cross sections of main structures of a conventional semiconductor device which are arranged in the order of steps of the fabrication method.

### DETAILED DESCRIPTION OF THE INVENTION

A semiconductor device and a fabrication method thereof according to an embodiment of the present invention are hereinafter described with reference to the drawings.

Described in the following embodiment is an example in which an MIS transistor having a thin gate insulating film is formed in a semiconductor substrate 1a (first region) and an MIS transistor having a thick gate insulating film is formed in a semiconductor substrate 1b (second region). Herein, the semiconductor substrate 1a and the semiconductor substrate 1b are parts of the same semiconductor substrate. A low voltage transistor formation region A is a region where an MIS transistor driven by the supply voltage of 1.2 V (hereinafter, referred to as 1.2-volt transistor) is formed as an MIS transistor having a thin gate insulating film, and a high voltage transistor formation region B is a region where an MIS transistor driven by the supply voltage of 3.3 V (hereinafter, referred to as 3.3-volt transistor) is formed as an MIS transistor having a thick gate insulating film. Herein, the 1.2-volt transistor and the 3.3-volt transistor are MIS transistors having the same conductivity type.

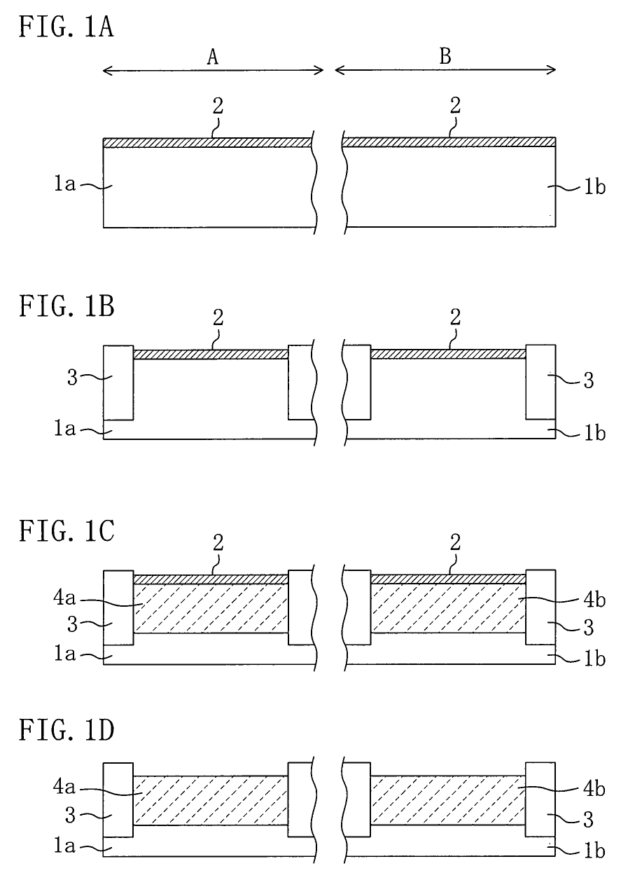

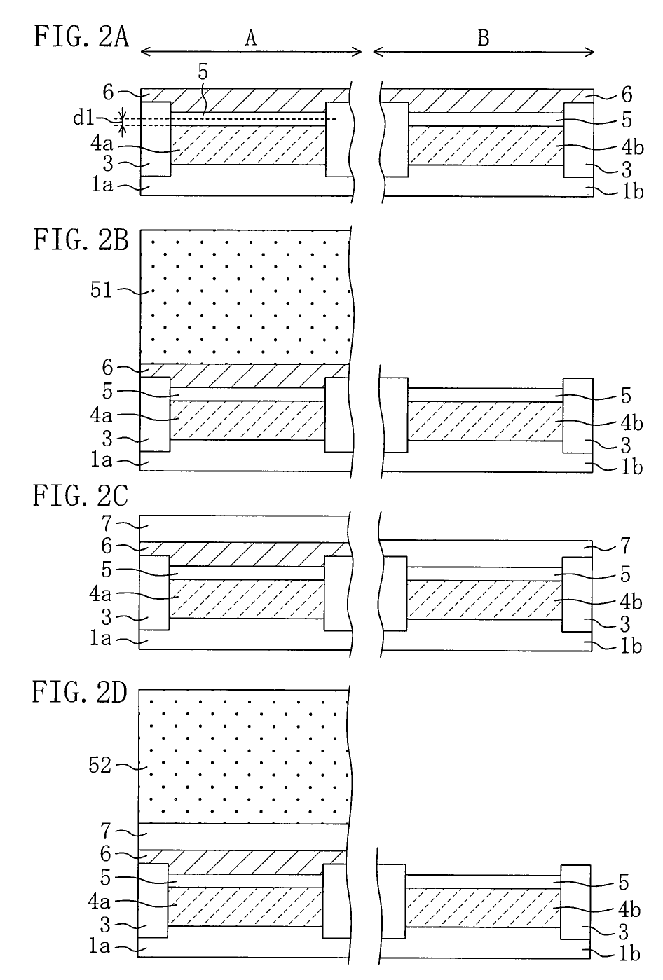

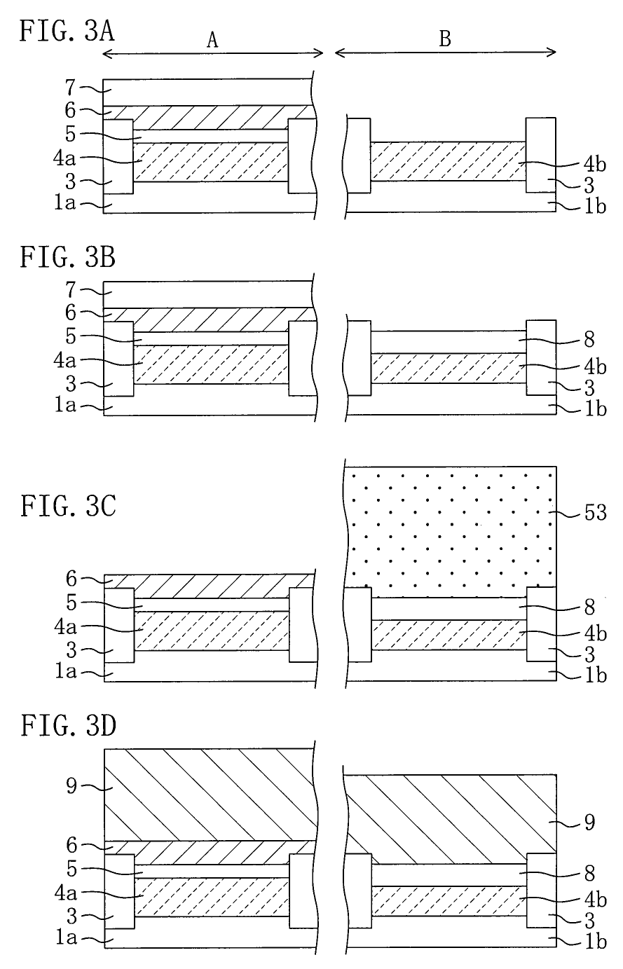

FIG. 1A through FIG. 1D, FIG. 2A through FIG. 2D and FIG. 3A through FIG. 3D are cross sections of a semiconductor device according to an embodiment of the present invention which are arranged in the order of steps of the fabrication method.

First, as shown in FIG. 1A, a sacrificial oxide film 2 is formed on the semiconductor substrate 1a and the semiconductor substrate 1b.

Next, as shown in FIG. 1B, isolation regions 3 are selectively formed in the upper portions of the semiconductor substrates 1a and 1b using, for example, an STI (shallow trench isolation) method, such that the isolation regions 3 define the low voltage transistor formation region A and the high voltage transistor formation region B.

Then, as shown in FIG. 1C, impurity layers 4a and 4b for controlling threshold voltage are formed in the upper portions of the active regions which are composed of the semiconductor substrates 1a and 1b defined by the isolation regions 3. In the case of n-type MIS transistors, p-type impurity ions are implanted to obtain p-type impurity layers 4a and 4b, and in the case of p-type MIS transistors, n-type impurity ions are implanted to obtain n-type impurity layers 4a and 4b. Herein, the sacrificial oxide film 2 has the function of preventing channeling during ion implantation.

Next, as shown in FIG. 1D, the sacrificial oxide film 2 is removed by wet etching using hydrofluoric acid (HF), buffered hydrofluoric acid (BHF) or the like, to expose the surfaces of the semiconductor substrates 1a and 1b.

Next, as shown in FIG. 2A, a thin gate insulating film 5 to be a gate insulating film of the 1.2-volt transistor is formed on the semiconductor substrates 1a and 1b. After that, a metal film 6 to be a metal gate is formed on the thin gate insulating film 5. Herein, the thin gate insulating film 5 is formed of a high dielectric constant gate insulating film whose dielectric constant is higher than that of a silicon oxide film, such as HfSiON film. In addition, because interface level increases if the HfSiON film is formed directly on the semiconductor substrates 1a and 1b, a silicon oxide film having a thickness of about 1 nm may be formed first on the semiconductor substrates 1a and 1b by thermal oxidation, and the HfSiON film having a thickness of about 2 nm may be then formed on the silicon oxide film by CVD. If the thin gate insulating film 5 is formed in this way, the increase in interface level is suppressed while the thin gate insulating film 5 has an equivalent oxide thickness of about 1.5 nm. Further, the physical thickness of the thin gate insulating film 5 is approximately 3 nm in total (The HfSiON film has a thickness of about 2 nm and the silicon oxide film has a thickness of about 1 nm). Gate leakage is therefore suppressed more than in the case where the thin gate insulating film 5 having a thickness of about 1.5 nm is formed only of a single silicon oxide film. In this case, the silicon oxide film having a thickness of about 1 nm is formed on the surfaces of the semiconductor substrates 1a and 1b by thermal oxidation, and therefore, the reduced thickness d1 of the semiconductor substrates 1a and 1b from their surfaces is about half the thickness of the silicon oxide film, that is, about 0.5 nm. In other words, the thickness of the impurity layer 4a is removed by about 0.5 nm from the surface of the semiconductor substrate 1a in the low voltage transistor formation region A.

The metal film 6 to be a metal gate prevents gate depletion, which results in improvement of the gate drivability of the semiconductor device, compared to the case where the gate electrode is formed only of polycrystalline silicon. As the metal film 6, a TiN film having a thickness of about 20 nm may be formed by CVD.

Next, as shown in FIG. 2B, a resist pattern 51 having an opening only in a region corresponding to the high voltage transistor formation region B is formed on the semiconductor substrate 1a. The metal film 6 in the high voltage transistor formation region B is removed by wet etching or dry etching, using the resist pattern 51 as a mask, thereby exposing the surface of the thin gate insulating film 5 on the semiconductor substrate 1b. At this time, the thin gate insulating film 5 functions as an etch stop.

Next, as shown in FIG. 2C, the resist pattern 51 is removed, and a silicon nitride film 7 having a thickness of about 10 nm is then formed by CVD on the metal film 6 in the low voltage transistor formation region A and on the thin gate insulating film 5 in the high voltage transistor formation region B.

Next, as shown in FIG. 2D, a resist pattern 52 having an opening in a region corresponding to the high voltage transistor formation region B is formed on the semiconductor substrate 1a. The silicon nitride film 7 in the high voltage transistor formation region B is removed by dry etching, using the resist pattern 52 as a mask, thereby exposing the surface of the thin gate insulating film 5 in the high voltage transistor formation region B. As a result, a mask film formed of the silicon nitride film 7 covering the metal film 6 on the semiconductor substrate 1a is obtained.

Then, as shown in FIG. 3A, a resist pattern 52 is removed, and the thin gate insulating film 5 in the high voltage transistor formation region B is then removed by wet etching using HF, BHF or the like, using the silicon nitride film 7 as a mask, thereby exposing the surface of the semiconductor substrate 1b in the high voltage transistor formation region B.

Next, as shown in FIG. 3B, a thick gate insulating film 8 is formed on the semiconductor substrate 1b in the high voltage transistor formation region B, using the silicon nitride film 7 as a mask for preventing oxidation. Herein, the gate insulating film 8 is formed by thermal oxidation so that the thickness thereof is about 7 nm or so. During this thermal oxidation, the surface of the semiconductor substrate 1a is prevented from receding because the silicon nitride film 7 exists above the semiconductor substrate 1a to cover the semiconductor substrate 1a, thereby protecting the low voltage transistor formation region A from oxidation. The metal film 6 is also covered by the silicon nitride film 7. The metal film 6 is therefore protected from oxidation during the thermal oxidation process. The HfSiON film composing the thin gate insulating film 5 may be crystallized under the high temperature atmosphere, and as a result, the drivability of the semiconductor device may decrease. To avoid such the crystallization, it is preferable that the thermal oxidation process is carried out at 1000° C. or lower. Other than this method, in which the thick gate insulating film 8 is formed only by the thermal oxidation at 1000° C. or lower, there are methods which can ensure process margins for suppressing the crystallization of the HFSiON film, of which the thin gate insulating film 5 is formed, by decreasing the temperature during the formation of the thick gate insulating film 8. For example, a silicon oxide film having a thickness of several nanometers may be formed by thermal oxidation at a temperature ranging from 800° C. to 1000° C. and then another silicon oxide film having a thickness of several nanometers may be formed on the silicon oxide film by CVD at a temperature ranging from 700° C. to 800° C.

Next, as shown in FIG. 3C, a resist pattern 53 having an opening in a region corresponding to the low voltage transistor formation region A is formed on the semiconductor substrate 1b. After that, the silicon nitride film 7 on the metal film 6 in the low voltage transistor formation region A is removed by dry etching, using the resist pattern 53 as a mask, thereby exposing the surface of the metal film 6 in the low voltage transistor formation region A. At this time, the metal film 6 functions as an etch stop. If the thick gate insulating film 8 is formed by thermal oxidation and CVD in the step shown in FIG. 3B, the silicon oxide film formed by the CVD remains on the silicon nitride film 7. This silicon oxide film can be removed by dry etching or wet etching using the resist pattern 53 as a mask, before the silicon nitride film 7 is removed by dry etching.

Next, as shown in FIG. 3D, the resist pattern 53 is removed, and a polycrystalline silicon film 9 having a thickness of about 100 nm is then formed by CVD on the metal film 6 in the low voltage transistor formation region A and on the thick gate insulating film 8 in the high voltage transistor formation region B. After that, the polycrystalline silicon film 9 and the metal film 6 are patterned to form a first gate electrode formed of the metal film 6 and the polycrystalline silicon film 9 on the semiconductor substrate 1a, with the thin gate insulating film 5 interposed therebetween, and form a second gate electrode formed of the polycrystalline silicon film 9 on semiconductor substrate 1b, with the thick gate insulating film 8 interposed therebetween.

As in the above, the present embodiment describes a semiconductor device which includes two types of gate insulating films each having a different thickness, namely, the gate insulating film 5 whose equivalent oxide thickness is about 1.5 nm and the gate insulating film 8 whose equivalent oxide thickness is about 7 nm, and includes a high dielectric constant gate insulating film and a metal gate in the MIS transistor having the thin gate insulating film 5 (in this case, 1.2-volt transistor). In this semiconductor device, the surface of the semiconductor substrate 1a in the low voltage transistor formation region A recedes by the smaller thickness of about 0.5 nm after formation of the impurity layer 4a for controlling threshold voltage. Variations in thickness reduction are diminished as the reduced thickness decreases. As a result, variations in threshold voltage of the above transistor are reduced.

Described hereinafter in detail are variations in impurity for controlling threshold voltage which are caused by variations in thickness reduction of the semiconductor substrate 1a from its surface according to the present invention, in comparison with the case of a conventional fabrication method.

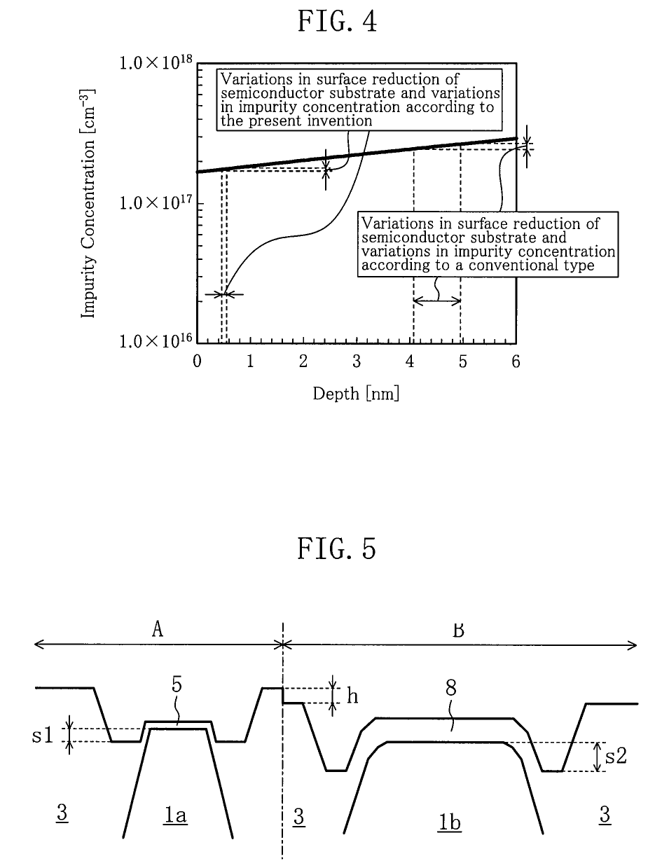

FIG. 4 shows an impurity profile near the surface of the semiconductor substrate 1a, when arsenic ions are implanted in the semiconductor substrate 1a at an acceleration energy of 80 KeV and an implantation dose of 1.0×10¹³ cm². The lateral axis of FIG. 4 indicates the depth from the surface of the semiconductor substrate 1a, and the longitudinal axis of FIG. 4 indicates the impurity concentration. The origin of the lateral axis indicates the surface of the semiconductor substrate 1a right after the ion implantation.

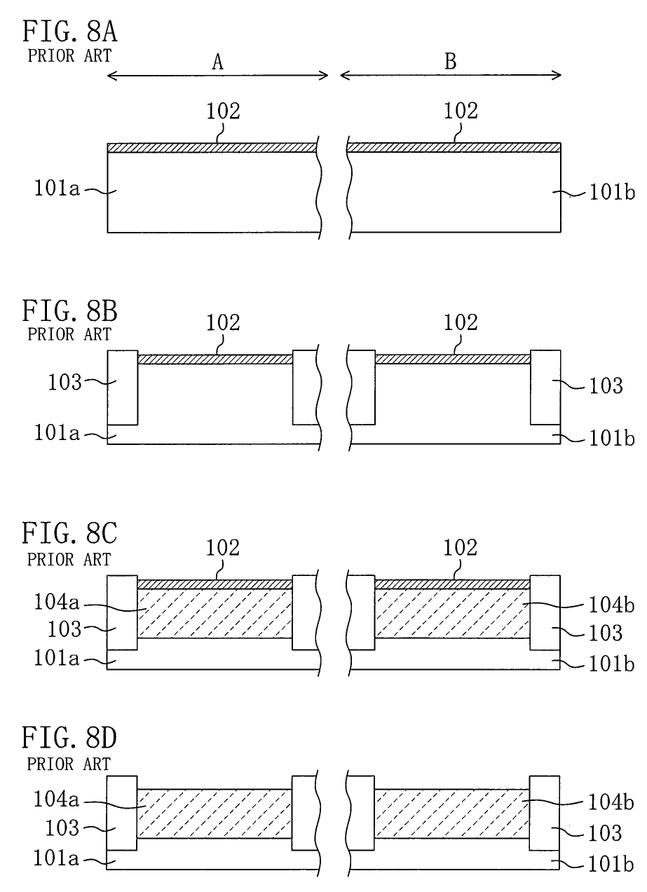

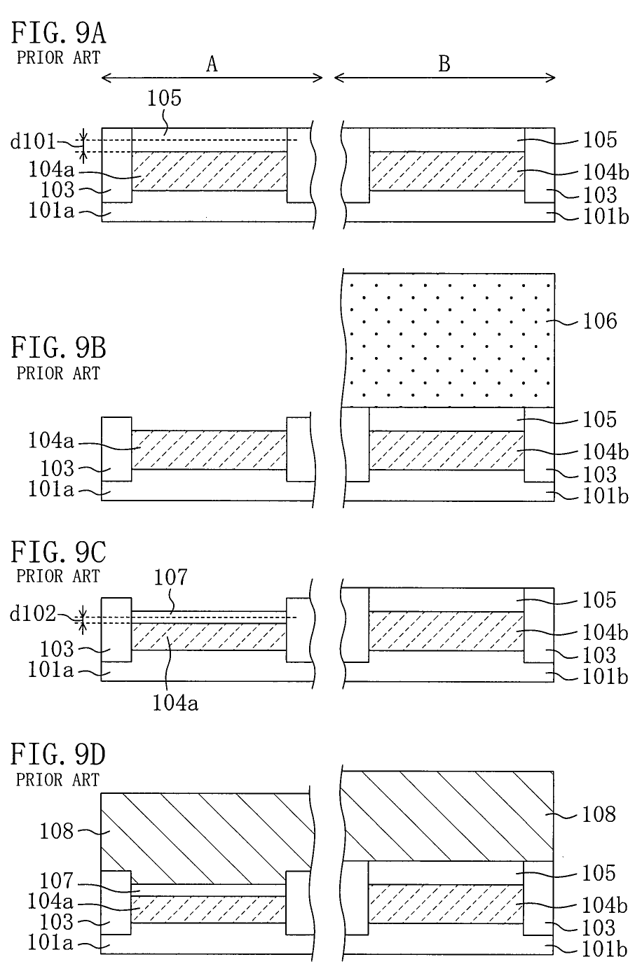

According to the conventional semiconductor device fabrication method described in BACKGROUND OF THE INVENTION (see FIG. 8A through FIG. 8D and FIG. 9A through FIG. 9D), the thickness of the semiconductor substrate 101a included in the MIS transistor (herein, 1.2-volt transistor) having a thin gate insulating film 107 is reduced from the surface thereof by the depth that is equal to the sum of the reduced thicknesses d101 and d102 of the semiconductor substrate 101a, after the formation of the impurity layer 104a for controlling threshold voltage. Specifically, d101 and d102 are expected to be 3.5 nm and 1 nm, respectively, and therefore, the sum is 4.5 nm. Suppose that variations in d101 and d102 are ±10 percent, the sum of the reduced thicknesses may vary ±0.45 nm. At this time, the variations in impurity concentration at the surface of the semiconductor substrate 101a are approximately ±4.1 percent as seen from FIG. 4.

In contrast, according to the semiconductor device fabrication method of the present invention, the thickness of the semiconductor substrate 1a included in the MIS transistor (herein, 1.2-volt transistor) having a thin gate insulating film 5 is reduced from the surface only by the depth d1, which is expected to be 0.5 nm, after the formation of the impurity layer 4a for controlling threshold voltage. Thus, suppose that variations in d1 are ±10 percent as with the above, the reduced thickness may vary ±0.05 nm. At this time, the variations in impurity concentration at the surface of the semiconductor substrate 1a are ±0.5 percent as seen from FIG. 4. Therefore the variations can be reduced to nearly one eighth of those caused by the conventional semiconductor device fabrication method.

Thus, according to the present embodiment, the thickness reduction of the semiconductor substrate included in the MIS transistor having a thin gate insulating film from the surface of the semiconductor substrate is reduced, and thus, variations in impurity concentration at the surface of the semiconductor substrate of the MIS transistor is diminished. As a result, variations in threshold voltage of the same transistor are reduced.

Described hereinafter are a structural feature of a semiconductor device according to the present embodiment and a further effect thereof, in comparison with a conventional semiconductor device.

FIG. 5 is a cross section of a semiconductor device along the gate width according to the present embodiment, and illustrates an MIS transistor having two different gate insulating films each having a different thickness, wherein a low voltage transistor formation region A and a high voltage transistor formation region B are electrically separated from each other by an isolation region 3. An MIS transistor having a thin gate insulating film 5 is formed in the low voltage transistor formation region A and an MIS transistor having a thick gate insulating film 8 is formed in the high voltage transistor formation region B. Herein, the step of the isolation region 3 at the boundary between the low voltage transistor formation region A and the high voltage transistor formation region B is referred to as step h.

In general, the isolation region 3 is formed of a silicon oxide film, and the surface of the isolation region 3 therefore recedes by wet etching using HF, BHF or the like. Hence, according to the above-described method of the present embodiment, the isolation region 3 in the low voltage transistor formation region A including the thin gate insulating film 5 is subjected to wet etching in one step as illustrated in FIG. 1D. On the other hand, the isolation region 3 in the high voltage transistor formation region B including the thick gate insulating film 8 is subjected to wet etching in two steps as illustrated in FIG. 1D and FIG. 3A. Thus, as shown in FIG. 5, the etching degree of the isolation region 3 in the high voltage transistor formation region B including the thick gate insulating film 8 is greater than the etching degree of the isolation region 3 in the low voltage transistor formation region A including the thin gate insulating film 5.

Consequently, as shown in FIG. 5, the level of the step h of the isolation region 3 at the boundary between the low voltage transistor formation region A and the high voltage transistor formation region B is higher at the side of low voltage transistor formation region A and lower at the side of the high voltage transistor formation region B. Further, in consideration of the difference between the wet etching degrees mentioned in the above, the depth s1 of a recess in the isolation region 3 near an active region of the low voltage transistor formation region A (distance from the surface of the active region in the semiconductor substrate 1a to the bottom face of the recess in the isolation region 3) is shallower than the depth s2 of a recess in the isolation region 3 near an active region of the high voltage transistor formation region B (distance from the surface of the active region in the semiconductor substrate 1b to the bottom face of the recess in the isolation region 3).

On the contrary, according to the conventional semiconductor device fabrication method described in BACKGROUND OF THE INVENTION (see FIG. 8A through FIG. 8D and FIG. 9A through FIG. 9D), the isolation region 103 in the low voltage transistor formation region A including the thin gate insulating film 107 is subjected to wet etching in two steps as illustrated in FIG. 8D and FIG. 9B, and the isolation region 103 in the high voltage transistor formation region B including the thick gate insulating film 105 is subjected to wet etching in one step as illustrated in FIG. 8D. Consequently, the level of a step of the isolation region 103 at the boundary between the low voltage transistor formation region A and the high voltage transistor formation region B is lower at the side of low voltage transistor formation region A including the thin gate insulating film 107 and higher at the side of the high voltage transistor formation region B including the thick gate insulating film 105. Further, in consideration of the difference between wet etching degrees, the depth of a recess in the isolation region 103 near an active region of the low voltage transistor formation region A including the thin gate insulating film 107 is greater than the depth of a recess in isolation region 103 near an active region of the high voltage transistor formation region B including the thick gate insulating film 105.

Considering the difference in wet etching degree in the low voltage transistor formation region A including the thin gate insulating film 5 between the case where the conventional method is used and the case where the method of the present embodiment is used, the depth s1 of the isolation region 3 near the active region of the low voltage transistor formation region A according to the method of the present invention is shallower than the corresponding depth according to the conventional method. In the present embodiment, wet etching degree is reduced, and therefore process variations are also reduced. Considering that the portion where the recess in the isolation region 3 and the semiconductor substrate 1a overlap one another serves as an active region, variations in the area of said portion is reduced more in the present embodiment than in the conventional case. This reduces variations in transistor properties.

### —Variations—

Variation 1 and Variation 2 of an embodiment of the present invention are hereinafter described with reference to the drawings. According to Variation 1 and Variation 2, the silicon nitride film 7 is removed in a different way from the one used in the above embodiment, taking the following possible situation in the above embodiment into account. Specifically, if the etch selection ratio between the thin gate insulating film 5 and the silicon nitride film 7 is not high enough in removing the silicon nitride film 7 by dry etching using the thin gate insulating film 5 as an etch stop in the step of FIG. 2D of the above embodiment, it is expected that variations in thickness of the silicon nitride film 7 in the wafer plane or variations in thickness of the thin gate insulating film 5 in the wafer plane increase, and as a result, the thin gate insulating film 5 may be etched by dry etching in part of the wafer plane. If this happens, the surface of the semiconductor substrate 1b in the high voltage transistor formation region is subjected to dry etching, which situation leads to a rough surface of the semiconductor substrate 1b and as a result, to increased variations in properties and reduction in reliability of the high voltage transistor.

To solve the above problems, Variation 1 and Variation 2 adopt the following fabrication methods, which are hereinafter described in detail.

### (Variation 1)

Described hereinafter are a semiconductor device and the fabrication method thereof according to Variation 1 of an embodiment of the present invention. As explained in the below, Variation 1 is for removing the silicon nitride film 7 in the high voltage transistor formation region B by wet etching, with the objective of increasing process margins of a method for removing the silicon nitride film 7.

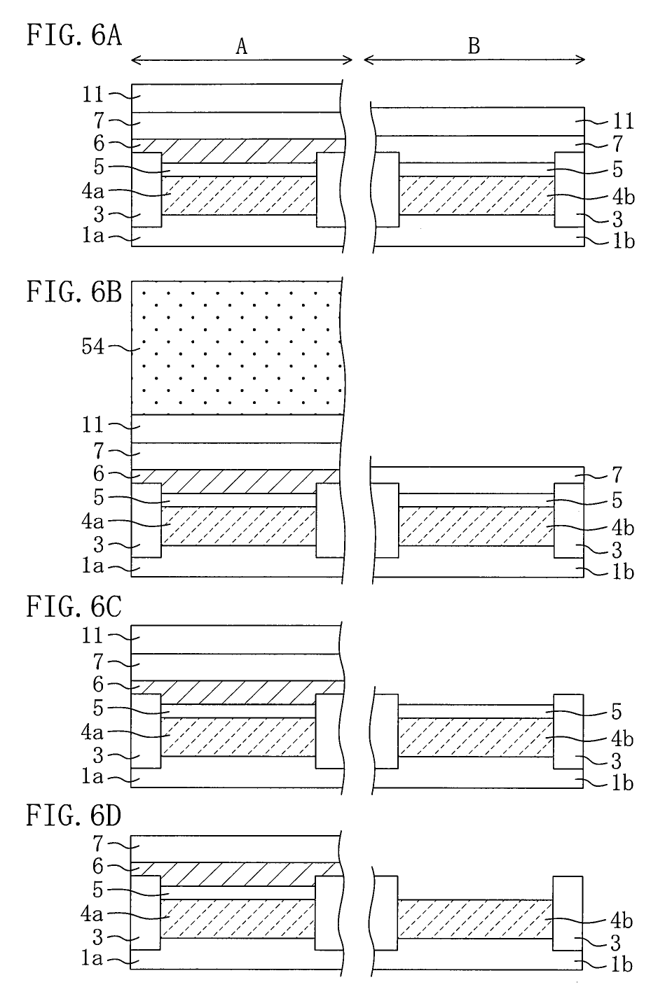

FIG. 6A through FIG. 6D are cross sections of a semiconductor device according to Variation 1 of an embodiment of the present invention which are arranged in the order of steps of the fabrication method. Detailed explanations about the steps of Variation 1 which are similar to the fabrication steps of the above-described embodiment are omitted.

First, the steps in FIG. 1A through FIG. 1D and FIG. 2A through FIG. 2C are carried out in the same manner.

Then, as shown in FIG. 6A, a silicon oxide film 11 having a thickness of about 20 nm is formed on the silicon nitride film 7 by CVD.

Next, as shown in FIG. 6B, a resist pattern 54 having an opening in a region corresponding to the high voltage transistor formation region B is formed above the semiconductor substrate 1a, and using this resist pattern 54 as a mask, the silicon oxide film 11 in the high voltage transistor formation region B is removed by wet etching using HF, BHF or the like, thereby exposing the surface of the silicon nitride film 7 in the high voltage transistor formation region B.

Next, as shown in FIG. 6C, the resist pattern 54 is removed. Then, using the silicon oxide film 11 as a mask, the silicon nitride film 7 in the high voltage transistor formation region B is removed by wet etching using hot phosphoric acid, thereby exposing the surface of the thin gate insulating film 5 in the high voltage transistor formation region B. The hot phosphoric acid achieves a satisfactory etch selection ratio in relation to the silicon oxide film and the HfSiON film which compose the thin gate insulating film 5. Hence, the thin gate insulating film 5 in the high voltage transistor formation region B cannot be etched.

Next, as shown in FIG. 6D, the silicon oxide film 11 in the low voltage transistor formation region A and the thin gate insulating film 5 in the high voltage transistor formation region B are removed by wet etching using HF, BHF or the like, thereby exposing the surface of the silicon nitride film 7 in the low voltage transistor formation region A and the surface of the semiconductor substrate 1b in the high voltage transistor formation region B.

Then, the steps of FIG. 3B through FIG. 3D are carried out in the same manner.

Thus, Variation 1 does not only achieve the same effects as the above embodiment but also provides the following effect: The thin gate insulating film 5 in the high voltage transistor formation region B is not etched, even if variations in thickness of the silicon nitride film 7 in the wafer plane or variations in thickness of the thin gate insulating film 5 in the wafer plane are great at the removal of the silicon nitride film 7 in the high voltage transistor formation region B.

### (Variation 2)

Described hereinafter are a semiconductor device and the fabrication method thereof according to Variation 2 of an embodiment of the present invention. As explained in the below, Variation 2 is for removing the silicon nitride film 7 in the high voltage transistor formation region B by dry etching, using the metal film 6 as an etch stop.

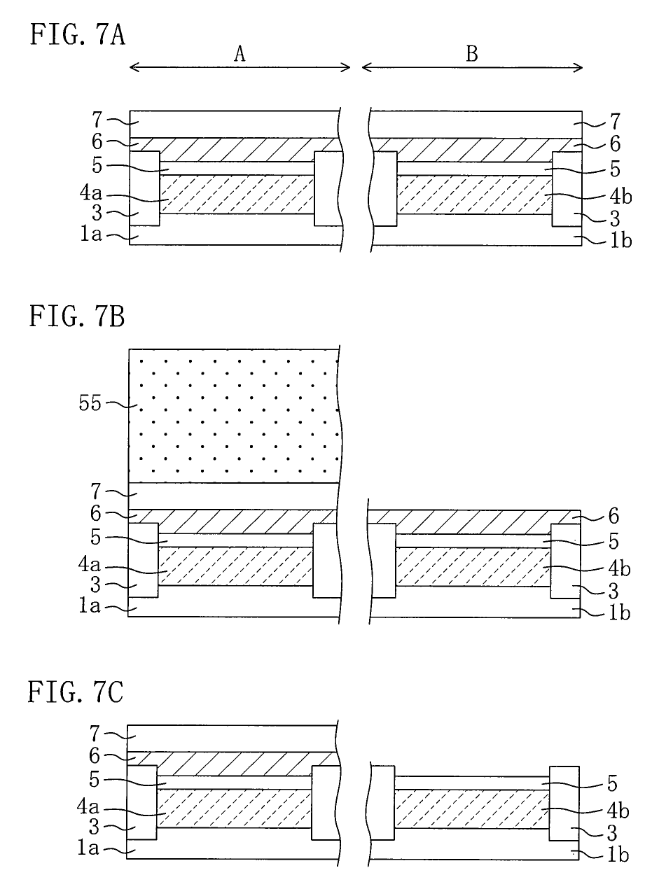

FIG. 7A through FIG. 7C are cross sections of a semiconductor device according to Variation 2 of an embodiment of the present invention which are arranged in the order of steps of the fabrication method. Detailed explanations about the steps of Variation 2 which are similar to the fabrication steps of the above-described embodiment are omitted.

First, the steps of FIG. 1A through FIG. 1D and FIG. 2A are carried out in the same manner.

Then, as shown in FIG. 7A, a silicon nitride film 7 is formed on the metal film 6 by CVD.

Next, as shown in FIG. 7B, a resist pattern 55 having an opening in a region corresponding to the high voltage transistor formation region B is formed above the semiconductor substrate 1a, and using this resist pattern 55 as a mask, the silicon nitride film 7 in the high voltage transistor formation region B is removed by dry etching, thereby exposing the surface of the metal film 6 in the high voltage transistor formation region B. At this time, the metal film 6 serves as an etch stop.

Next, as shown in FIG. 7C, the resist pattern 55 is removed. Then, using the silicon nitride film 7 as a mask, the metal film 6 in the high voltage transistor formation region B is removed by wet etching, thereby exposing the surface of the thin gate insulating film 5 on the semiconductor substrate 1b.

Then, the steps of FIG. 3A through FIG. 3D are carried out in the same manner.

Thus, Variation 2 does not only achieve the same effects as the above embodiment but also provides the following effect: The thin gate insulating film 5 in the high voltage transistor formation region B is not etched, even if variations in thickness of the silicon nitride film 7 in the wafer plane or variations in thickness of the thin gate insulating film 5 in the wafer plane are great at the removal of the silicon nitride film 7 in the high voltage transistor formation region B.

While the above embodiment is described in connection with the case in which the supply voltage for a transistor having the thin gate insulating film 5 is 1.2 V and the supply voltage for a transistor having the thick gate insulating film 8 is 3.3 V, supply voltages are not limited to these figures. While an HfSiON film is used as a high dielectric constant film which is a component of the thin gate insulating film 5, other high dielectric constant films, such as a ZrSiOₓ, film and Al₂O₃ film, may also be used. While TiN film is used as the metal film 6 of a metal gate, other materials such as TaN may also be used. The materials of the metal gates of the MIS transistors formed in the low voltage transistor formation region A and the high voltage transistor formation region B may be of different conductivity types, N-type and P-type, or may be of the same conductivity type, N-type or P-type. These structures are easily thinkable from the above embodiment and the same effects as above are therefore obtained.

As above, the present invention is useful as a semiconductor device which includes a plurality of gate insulating films each having a different thickness and includes a high dielectric constant gate insulating film and a metal gate, and a fabrication method of the same.

What is claimed is:

1. A semiconductor device comprising:
a first MIS transistor in a first region of a semiconductor substrate; and
a second MIS transistor formed in a second region of the semiconductor substrate that is different from the first region, wherein
the first MIS transistor includes:
a first gate insulating film formed in the first region; and
a first gate electrode formed of a metal film and a polycrystalline silicon film, which are stacked in this order on the first gate insulating film,
the second MIS transistor includes:
a second gate insulating film formed in the second region; and
a second gate electrode formed of a polycrystalline silicon film on the second gate insulating film,
an equivalent oxide thickness of the first gate insulating film is thinner than an equivalent oxide thickness of the second insulating film, and
a level of a surface of the semiconductor substrate in the first region is higher than a level of a surface of the semiconductor substrate in the second region.

2. The semiconductor device of claim 1, wherein the first gate insulating film includes an insulating film whose dielectric constant is higher than that of a silicon oxide film.

3. The semiconductor device of claim 1, wherein the second gate insulating film is a silicon oxide film.

4. The semiconductor device of claim 1, further comprising an isolation region which defines each of the first region and the second region and electrically separates the first region and the second region from one another,
wherein at a boundary between the first and second regions a level of the isolation region on the first region side is higher than a level of the isolation region on the second region side.

5. The semiconductor device of claim 1, further comprising an isolation region which defines each of the first region and the second region and electrically separates the first region and the second region from one another,
wherein a depth of a recess of the isolation region in the first region is shallower than a depth of a recess of the isolation region in the second region.

6. The semiconductor device of claim 1, wherein
the first MIS transistor is a low voltage transistor, and
the second MIS transistor is a high voltage transistor.

7. The semiconductor device of claim 1, wherein the first MIS transistor and the second MIS transistor have the same conductivity type.

8. A method for fabricating a semiconductor device, comprising the steps of:
(a) forming a first gate insulating film and a metal film in this order in a first region and a second region of the semiconductor substrate;
(b) removing the metal film in the second region;
(c) after step (b) removing the first gate insulating film in the second region;
(d) after step (c) forming in the second region a second gate insulating film having an equivalent oxide thickness greater than an equivalent oxide thickness of the first gate insulating film, with the first gate insulating film and the metal film remaining in the first region;
(e) after step (d) forming a polycrystalline silicon film on the metal film exposed in the fist region and on the second gate insulating film exposed in the second region; and
(f) patterning the polycrystalline silicon film and the metal film to form a first gate electrode composed of the metal film and the polycrystalline silicon film on the first gate insulating film in the first region and form a second gate electrode composed of the polycrystalline silicon film on the second gate insulating film in the second region.

9. The method of claim 8, further comprising the step (g) of forming a mask film for covering the metal film in the first region after step (b) and before step (c), wherein step (c) includes removing the first gate insulating film in the second region by etching using the mask film as a mask.

10. The method of claim 9, wherein step (g) includes the steps of:
(g1) forming a silicon nitride film in the first region and the second region; and
(g2) removing the silicon nitride film in the second region by dry etching using a resist pattern covering the silicon nitride film in the first region as a mask, thereby obtaining the mask film composed of the silicon nitride film.

11. The method of claim 9, wherein step (g) includes the steps of:
(g1) forming a silicon nitride film in the first region and the second region; and
(g2) removing the silicon nitride film in the second region by wet etching using a silicon oxide film covering the silicon nitride film in the first region as a mask, thereby obtaining the mask film composed of the silicon nitride film.

12. The method of claim 8, wherein step (b) includes the steps of:
(b1) forming a silicon nitride film on the metal film in the first and second regions;
(b2) removing the silicon nitride film in the second region, thereby obtaining a mask film composed of the silicon nitride film covering the metal film in the first region; and
(b3) removing the metal film in the second region by etching using the mask film as a mask, and step (c) includes removing the first gate insulating film in the second region by etching using the mask film as a mask.

13. The method of claim 9, wherein step (d) includes the step of forming the second gate insulating film by thermal oxidation using the mask film as a mask for preventing oxidation.

14. The method of claim 9, wherein step (d) includes the step of forming a first silicon oxide film by thermal oxidation and then forming a second silicon oxide film on the first silicon oxide film by CVD, thereby obtaining the second gate insulating film composed of the first silicon oxide film and the second silicon oxide film.

15. The method of claim 8, wherein step (a) includes the step of forming in the first and second regions a silicon oxide film and an insulating film having a dielectric constant higher than a dielectric constant of the silicon oxide film in this order, thereby obtaining the first gate insulating film.

16. The method of claim 8, wherein step (c) includes the step of removing the first gate insulating film by wet etching using hydrofluoric acid.
